(19) United States
(12) Patent Application Publication
(10) Pub. No.: US 2007/0110259 A1
(43) Pub. Date: May 17, 2007

(54) Method and system for comparing audio signals and identifying an audio source

(75) Inventors: Andrea Mezzasalma, Seveso (IT); Andrea Lombardo, Milano (IT); Stefano Magni, Milano (IT)

Correspondence Address: MODIANO & ASSOCIATI, Via Meravigli, 16, MILAN, 20123, IT

(73) Assignee: GFK EURISKO S.R.L.

(21) Appl. No.: 11/528,504

(22) Filed: Sep. 28, 2006

(30) Foreign Application Priority Data
Nov. 16, 2005 (IT) MI2005A002196

(51) Int. Cl. H03G 5/00; H04R 5/00

(52) U.S. Cl. 381/99; 381/98; 381/1

(57) ABSTRACT

An audio tagging method adapted to insert, in audio generated by an audio source and represented in the frequency domain, an identification code which comprises a predefined number of bits, associating with each bit of the code a corresponding frequency interval and applying a bandpass filter centered on each of the frequency intervals associated with one of the bits of the code, such that: if the bit has the value 1, the value of the corresponding frequency interval is amplified; if the bit has the value 0, the value of the corresponding frequency interval is attenuated.

The present invention relates to a method for audio tagging, particularly for identifying an audio source which has emitted an audio signal, a system which comprises an audio tagging device, and a tagged audio recognition device.

### BACKGROUND OF THE INVENTION

Currently, the number of radio and television stations that broadcast their signals wirelessly or by cable has become very large and the schedules of each broadcaster are extremely disparate.

Both in an indoor domestic or working environment and outdoors, we are constantly subject to hearing, intentionally or unintentionally, audio that arrives from radio and television sources.

Listening and viewing of a radio or television program can be classified in two different categories: of the active type, if there is a conscious and deliberate attention to the program, for example when watching a movie or listening carefully to a television or radio newscast; of the passive type, when the sound waves that reach our ears are part of an audio background, to which we do not necessarily pay particular attention but which at the same time does not avoid our unconscious assimilation.

Indeed in view of the enormous number of radio and television stations available, it has become increasingly difficult to estimate which networks and programs are the most followed, either actively or passively.

As is known, this information is of fundamental importance not only for statistical purposes but most of all for commercial purposes.

In this context, so-called sound matching techniques, i.e., techniques for recording audio signals and subsequently comparing them with the various possible audio sources in order to identify the source to which the user has actually been exposed at a certain time of day, have been developed.

Sound recognition systems often use portable devices, known as meters, which collect the ambient sounds to which they are exposed and extract special information from them. This information, known technically as “sound prints”, is then transferred to a data collection center. Transfer can occur either by sending the memory media that contain the recordings or over a wired or wireless connection to the computer of the data collection center, typically a server which is capable of storing large amounts of data and is provided with suitable processing software.

The data collection center also records continuously all the radio or television stations to be monitored, making them available on its computer.

In order to define which radio or television stations have been heard during the day, each sound print acquired by a meter at a certain instant in time is compared with said recordings of each of the radio and television stations, only as regards a small time interval in the neighborhood of the instant being considered, in order to identify the station, if any, to which the meter was exposed at that time.

Typically, in order to minimize the possibility of obtaining false positives and false negatives, this assessment is performed on a set of consecutive sound prints.

Co-pending U.S. Ser. No. 11/431,857 by the same Applicant, the text whereof is included herein in full by reference, discloses a new advanced sound matching method, which uses certain characteristics of the frequency spectrum of the sound in order to determine the match between the audio detected by a meter and the audio source.

In particular, the fundamental index of association between the sound print acquired by a meter at a certain time t and the recording of the audio source, for example a radio or television, at the time t′, is represented by a percentage of derivatives which have the same sign in the sample acquired by the meter (“meter sample”) and in the source sample, weighed with the absolute value of each derivative of the source sample.

This sound matching procedure is sufficient, in itself, to identify with considerable assurance and effectiveness the audio source, for example the radio or television station, to which the meter is exposed.

In some cases, however, different radio or television stations may broadcast simultaneously the same program, for example newscasts, live concerts, and others.

In this situation, the sound matching procedure is not sufficient in itself to identify correctly the individual radio station to which the meter is actually exposed.

Moreover, it may be necessary to know the distribution platform (AM, FM, DAB, satellite, digital terrestrial television, the Internet) via which listening occurs. In this case also, the sound matching procedure in itself is unable to yield a safe result.

Known systems overcome this problem by inserting in certain points of the output audio, for example in the points of the audio where time or frequency masking conditions occur, an audio frequency on which an identification code is modulated. In this case, portable or fixed meters do not extract “sound prints” as occurs for sound matching, but identify the code, if any, that is present within the audio.

However, these techniques are affected by some important limitations. In particular, it is not possible to use the same devices used for sound matching but it is necessary to use devices which can operate specifically for recognizing codes within certain frequencies.

Moreover, the insertion of these codes often entails degradation of the audio signal, introducing unwanted audible signals or hissing.

### SUMMARY OF THE INVENTION

The aim of the present invention is to overcome the limitations described above by tagging the audio before it is broadcast by the corresponding audio source, so as to allow recognition of the source even if it is not possible to identify the audio correctly by means of sound matching techniques, so that the tagging is inaudible for the human ear and therefore does not entail signal degradation.

Within this aim, an object of the present invention is to tag the audio so that it is recognizable by means of ordinary sound matching techniques, particularly even by receivers as disclosed in co-pending U.S. Ser. No. 11/431,857 by the same Applicant.

This aim and this and other objects, which will become better apparent hereinafter, are achieved by an audio tagging method which is adapted to insert, in audio generated by an audio source and represented in the frequency domain, an identification code which comprises a predefined number of bits, which comprises the steps of: associating with each bit of the code a corresponding frequency interval; applying a bandpass filter centered on each of the frequency intervals associated with the bits of the code, such that: if the bit has the value 1, the value of the corresponding frequency interval is amplified; if the bit has the value 0, the value of the corresponding frequency interval is attenuated.

This aim and this and other objects are also achieved by an audio tagging device which is adapted to insert, in audio generated by an audio source and represented in the frequency domain, an identification code which comprises a predefined number of bits, wherein the tagging device comprises: means for associating with each bit of the code a corresponding frequency interval; means for applying a bandpass filter which is centered on each of the frequency intervals associated with the bits of said code, such that: if the bit has the value 1, the value of the corresponding frequency interval is amplified; if the bit has the value 0, the value of the corresponding frequency interval is attenuated.

Preferably, the identification code comprises 10 to 20 bits, preferably 15.

Advantageously, the bandpass filter covers frequency intervals which are adjacent to the frequency interval on which it is centered, amplifying or attenuating said adjacent intervals to a lesser extent than the interval on which the bandpass filter is centered.

### BRIEF DESCRIPTION OF THE DRAWINGS

Further characteristics and advantages of the invention will become better apparent from the following detailed description, given by way of non-limiting example and accompanied by the corresponding figures, wherein:

FIG. 1 is a schematic block diagram of the audio tagging process according to the present invention;

FIGS. 2 and 3 are schematic exemplifying views of the amplification and attenuation of frequency intervals selected to represent bits of an identification code used to tag audio.

### DESCRIPTION OF THE PREFERRED EMBODIMENTS

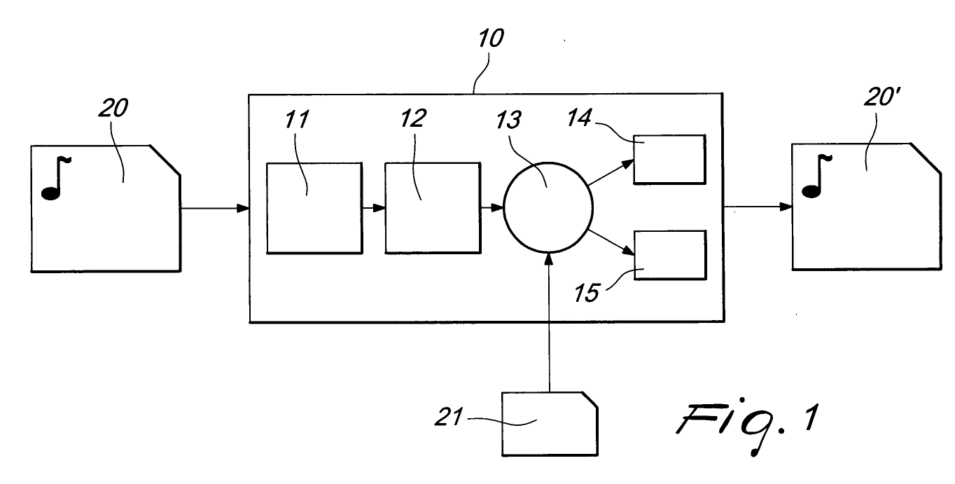

An exemplifying data processing architecture of the tagging system 1 according to the present invention is summarized in the block diagram of FIG. 1.

In particular, FIG. 1 illustrates an audio tagging device 10, which comprises a sampler 11, a device 12 for converting the sampled signal in the frequency domain, an encoder 13, and amplifier and attenuator bandpass filters 14 and 15 respectively.

Operation of the tagging device is as follows.

At a radio or television station or at any other audio source which is adapted to generate audio and on which the audio tagging device 10 has been made available, an audio file 20 is passed through the sampler 11, which samples the audio according to predefined parameters, for example by using a frequency of 44100 kHz with a resolution of 16 bits per sample.

The converter 12 acquires the samples and performs the Fourier transforms in order to switch from the time domain to the frequency domain.

The encoder 13 receives in input an identification code 21 to be used to tag the audio. The code is represented in binary form and each bit of the code can of course assume the value 0 or the value 1.

For each bit, a corresponding frequency F(i) is identified which is adapted to represent the bit (in the present text, the expression F(i) or the expression Fᵢ will be used equivalently).

In particular, if the n-th bit is equal to “0”, then the sign of the derivative related to the frequency F(i), used to represent that bit, must be negative, while if the bit is equal to “1”, then the sign of the derivative related to the frequency F(i) must be positive.

For this purpose, a filter 14 designed to amplify F(i) is applied in the first case. In the second case, a filter 15 designed to attenuate F(i) is applied.

The same operation is performed for each bit of the code, thus producing in output a modified audio file 20′, which is tagged with the code 21.

The tagging principle according to the present invention therefore entails attenuating or boosting certain audio frequencies, so that the signs of the derivatives

D′i=1 if Fᵢ>Fᵢ₋₁

D′i=0 if Fᵢ<=Fᵢ₋₁

change value, for a sufficient number of samples, according to a predefined pattern.

In particular, a set of n frequencies Fᵢ is selected, taking care that the minimum difference between the different values of i is equal to, or greater than, the size of the bandpass filter that is used.

Theoretically, each Fᵢ can be associated with a single bit of an identification code. If the value of a given bit must be set equal to 1, the audio frequency Fᵢ that corresponds to said bit is boosted systematically if a adapted masking condition is found. If the value of a given bit must be set equal to 0, the audio frequency Fᵢ that corresponds to said bit is attenuated systematically if a suitable masking condition is found.

For the uses for which the system is intended, it is sufficient to use for the identification code a number of bits ranging from 10 to 20, for example 15. In this case it is therefore possible to use codes from 0 to 32767 (2¹⁵), being also able to associate each bit of the code with more than one Fᵢ among the ones available. In this manner, it is possible to have a higher assurance that the tagging is effective for any type of audio.

The code thus composed must of course assume different values as a function of the distribution platform that is used or as a function of the radio/TV stations, and in particular some bits can be associated with the platform, others can be associated with the station, others can indicate more or less precisely the date and time of the broadcast, this last tagging being useful for time-shifted listening analysis.

In a preferred embodiment, the bandpass filter that is used also acts on the frequencies that directly precede or follow the selected frequency Fᵢ, for example on the directly preceding frequency and on the directly subsequent frequency.

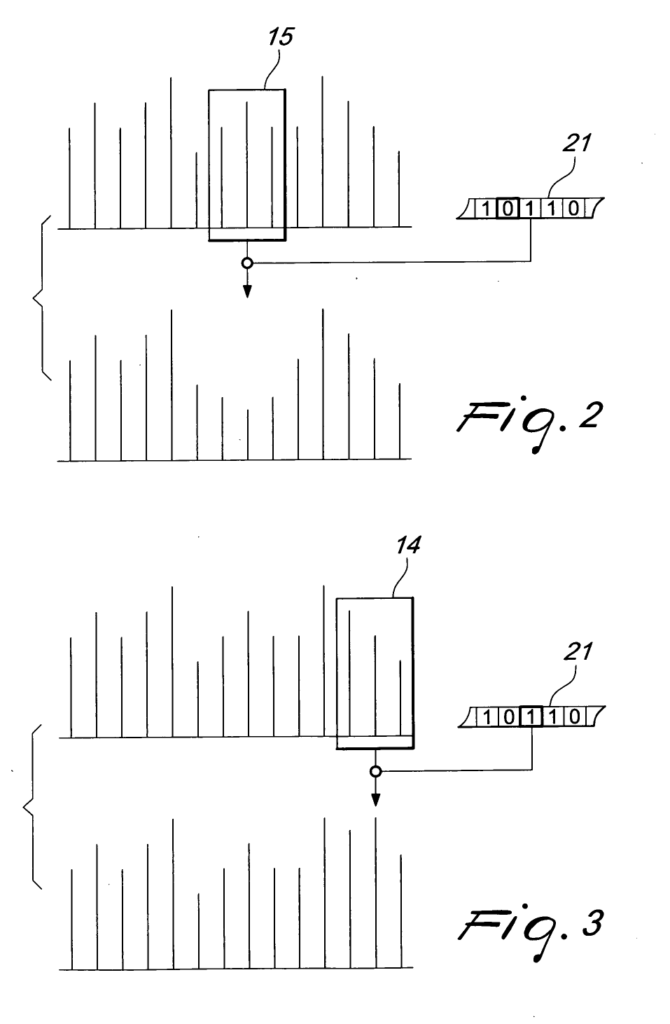

For example, as shown schematically in FIG. 2, assuming that one wishes to set to “1” the bit of the identification code associated with Fᵢ, the filter 14 is aimed at increasing Fᵢ and has such a range as to increase to a lesser extent also Fᵢ₋₁ and Fᵢ₊₁.

In this manner, the probability is increased that the derivatives D′ᵢ and D′ᵢ₋₁ assume the value “1” even though in the absence of the tagging they would have had the value “0”, and the probability is increased that D′ᵢ₊₁ and D′ᵢ₊₁ assume the value “0” even though in the absence of the tagging they would have had the value “1”.

Vice versa, as shown schematically in FIG. 3, assuming that one wishes to set to “0” the bit of the identification code associated with Fᵢ, the filter 15 is intended to attenuate Fᵢ and has such a range as to attenuate to a lesser extent also Fᵢ₋ₗ and Fᵢ₊₁.

This increases the probability that D′ᵢ and D′ᵢ₋₁ assume the value “0”, even though in the absence of the tagging they would have had the value “1”, and the probability that the derivatives D′ᵢ₊₁, and D′ᵢ₊₂ assume the value “1”, even though in the absence of the tagging they would have had the value “0”.

With reference to the inventive concept described above, an example of tagging according to the invention, performed so that it is undetectable to the human ear, according to the psychoacoustic models normally used in the field, is now detailed merely by way of non-limiting example.

The example given here provides for audio sampled at 44100 Hz. The person skilled in the art obviously understands without effort how to modify the subsequent data if a different sampling frequency is used.

If the signal is stereo, one proceeds for each of the two stereo audio channels separately.

At the time 1, 2048 successive samples (S₁, . . . , S₂₀₄₈), equal to approximately 0.046 seconds, are extracted from the audio recording file.

A Hanning window is applied to the samples:

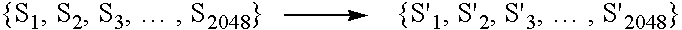

A routine for spectrum calculation is then applied, giving rise to 128 frequency intervals F¹₁, F¹₁₂₈ which are equidistant in the interval ranging from 0 to 3150 Hz, in a manner similar to what is done by the standard sound matching procedure disclosed in co-pending U.S. Ser. No. 11/431,857.

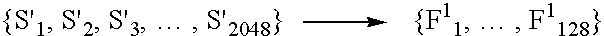

At the time 2, 2048 consecutive samples (S₁₀₂₅, . . . , S₃₀₇₂) are extracted from the audio recording file, shifting forward by 1024 samples, i.e., by approximately 0.023 seconds; half of said samples overlap the ones used in the preceding step.

A Hanning window is applied to these samples 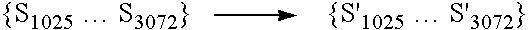
and then a spectrum calculation routine is applied

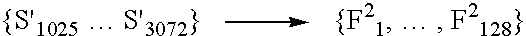

This process is repeated in a similar manner until one obtains, at the time 5. 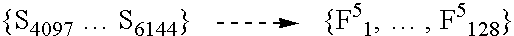
The original samples are also duplicated 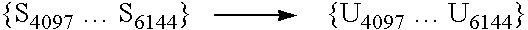
so that U₄₀₉₇ . . . U₆₁₄₄ can be modified subsequently in an iterative manner and then sent in output to the sound card.

At the time 5, the psychoacoustic models known in the field are applied in order to identify the frequency masking thresholds 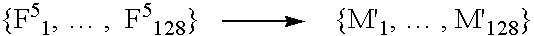
and the time masking thresholds 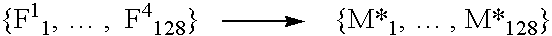
and finally the absolute masking thresholds

{M₁, . . . , M₁₂₈}

where Mᵢ=max (M*ᵢ, M′ᵢ)

For each Fᵢ associated with a bit of the preset identification code, existence of the condition Fᵢ<Mᵢ is checked.

If Fᵢ<Mᵢ and the bit associated with Fᵢ has the value 1, a digital bandpass filter centered on Fᵢ is applied 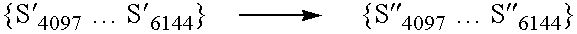
so that by calculating according to the usual criterion 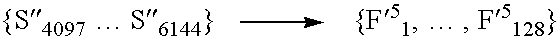 F′⁵ᵢ+F⁵ᵢ=Mᵢ
and so that all the values F′⁵₂ . . . F′⁵ᵢ₋₂ and F′⁵ᵢ₊₂ . . . F′⁵₁₂₈ are close to 0. One can also work so that F′⁵ᵢ+F⁵ᵢ is always less than Mᵢ by a given proportion, such as to avoid any risk of audibility of the equalization.

Each value of the set U₄₀₉₇ . . . U₆₁₄₄ is then increased by the corresponding value of the set S″₄₀₉₇ . . . S″₆₁₄₄, thus obtaining that by recalculating 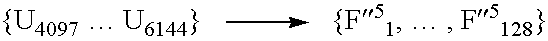
F″⁵ᵢ has a value close to Mᵢ, while the values F″⁵₂ . . . F″⁵ᵢ₋₂ and F″⁵ᵢ₊₂ . . . F″⁵₁₂₈ remain substantially unchanged with respect to F⁵₂ . . . F⁵ᵢ₋₂ and F⁵ᵢ₊₂ . . . F⁵₁₂₈.

If Fᵢ<Mᵢ and the bit associated with Fᵢ has a value 0, a digital bandpass filter centered on Fᵢ is applied 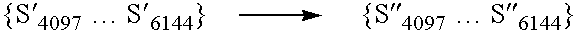
so that by calculating according to the ordinary criterion 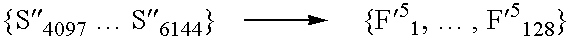
F′⁵ᵢ=F⁵ᵢ and all the values F′⁵₂ . . . F′⁵ᵢ₋₂ and F′⁵ᵢ₊₂ . . . F′⁵₁₂₈ are close to 0. In this case also, it is also possible to make F′⁵; always lower than F′⁵; by a given proportion which is adapted to avoid the risk of audibility of the equalization.

Each value of the set U₄₀₉₇ . . . U₆₁₄₄ is therefore decreased by the corresponding value of the set S″₄₀₉₇ . . . S″₆₁₄₄, thus obtaining that by recalculating 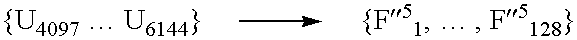
F″⁵ᵢ has a value close to 0, while the values F″⁵₂ . . . F″⁵ᵢ₋₂ and F″⁵ᵢ₊2 . . . F″⁵₁₂₈ remain substantially unchanged with respect to F⁵₂ . . . F⁵ᵢ₋₂ and F⁵ᵢ₊₂ . . . F⁵₁₂₈.

The procedure is then iterated for each Fᵢ associated with a bit of the identification code, at the time 5.

Again at the time 5, the modified samples are sent in output to the audio card:

{U₄₀₉₇ . . . U₅₁₂₀}

The entire procedure is then iterated at the time 6, so that starting from

{S₅₁₂₁ . . . S₇₁₆₈}

the following are modified further and sent in output to the audio card:

{U₅₁₂₁ . . . U₆₁₄₄}

and the following are generated from scratch:

{U₆₁₄₅ . . . U₇₁₆₈}

The procedure is then repeated at the time 7 and at subsequent times, having potentially an infinite duration.

The person skilled in the art understands without effort that it is possible to optimize the procedure described herein in various manners, particularly by preserving the bandpass filters in the frequency domain, multiplying each of them by a suitable parameter and adding their result in a single filter to be used in a so-called “FFT convolution”.

These optimizations or variations do not alter the operating principle of the system described here.

As regards now identification of the tagged audio, the basic identification of the radio or television station or audio source to which the meter has been exposed and the synchronization between the meter sample and the radio/TV recording is performed on the basis of the standard sound matching procedure.

At this point, in order to allow quick identification of the identification code, it is convenient to have, for each period of 0.203 seconds and for each Fᵢ with which a bit of the identification code has been associated, values Dᵢ₋₁, Dᵢ, Dᵢ₊₁, Dᵢ₊₂ for the two cases:

D¹ᵢ₊₁, D¹ᵢ, D¹ᵢ₊, D¹ᵢ₊₂ if the bit associated with Fᵢ is set to 1;

D⁰ᵢ₋₁, D⁰ᵢ, D⁰ᵢ₊₁, D⁰ᵢ₊₂ if the bit associated with Fᵢ is set to 0.

These values can be obtained in various manners, all of which are within the scope of the inventive concept on which the invention is based. For example, it is possible to receive the signal that arrives from the individual station/platform combinations, record the audio separately and calculate the values Dᵢ separately.

The software or hardware device located at the stations or at the distribution points might also, directly after tagging an audio segment, analyze said segment in order to identify the changes in the values Dᵢ and transmit over the Internet the different values to the processing center, optionally together with the recording of the original unduplicated audio.

Moreover, it is possible to transmit via a single platform, for example FM, the unmodified channel and therefore receive said signal and record its audio, and then repeat the tagging operation at the calculation center, thus obtaining, barring minor differences due to the quality of the radio broadcast, the values Dᵢ as a function of the value assumed by the corresponding bit of the code; this last case requires a slightly more complex statistical treatment, which is not described here but can be derived easily by the person skilled in the art.

The process for identifying the code continues for a period which is long enough to ensure the certainty of the result, for example one minute, during which, by sampling five periods of 0.203 seconds every 6 seconds, there are 50 meter samples detected at the corresponding time t, wherein 1 <=t<=50.

One thus obtains, for a given Fᵢ associated with a bit of the code, the following sets:

a first set of the values detected by the meter

{D′_{i-,1},D′_{i,1}, D′_{i+1,1} ,D′_{i+2,1} . . . D′_{i-1,t},D′_{i,t},D′_{i+1,t},D′_{i+2,t} . . . D′_{i-1,50},D′_{i,50},D′_{i+1,50},D′_{i+2,50}}

a second set of expected values if the value 1 has been assigned to the bit of the code associated with Fᵢ

{D¹_{i-1,1}, D¹_{i,1},D¹_{i+1,1}, D¹_{i+2,1} . . . D¹_{i-1,t},D¹_{i,t},D¹_{i+1,t},D¹_{i+2,t} . . . D¹_{i-1,50},D¹_{i,50}, D¹_{i+1,50},D¹_{i+2,50}}

a third set of expected values if the value 0 has been assigned to the bit of the code associated with Fᵢ

{D⁰_{i-1,1},D⁰_{i,1},D⁰_{i+1,1},D⁰_{i+2,1} . . . D⁰_{i-1,t},D⁰_{i,t},D⁰_{i+1,t},D⁰_{i+2,t} . . . D⁰_{i-1,50}, D^{0,50}, D⁰_{i+1, 50},D⁰_{i+2,50}}

Starting from these three sets, one then calculates, for i−1<=j<=i+2 and for 1<=t<=50, the number P of cases in which D¹_{j,t} is different from D⁰_{j,t} and simultaneously D′_{j,t} is equal to D¹_{j,t} and the number Q of cases in which D¹_{j,t} is different from D⁰_{j,t} and simultaneously D′_{j,t} is equal to D⁰_{j,t}.

At this point, a common statistical parametric or nonparametric test is applied in order to determine whether P is significantly greater than Q or vice versa.

If P is significantly greater than Q, the value 1 is assigned to the bit associated with Fᵢ, while if Q is significantly greater than P, the value 0 is assigned to the bit associated with Fᵢ.

If there is no significant difference between P and Q, the test can be performed on a longer period of time or, if this is not possible, the result remains undetermined.

If, as hypothesized earlier, each bit of the code is associated with two or three different Fᵢ, the test is applied to the sum of the P and of the Q generated by each of the two or three different Fᵢ, thus increasing the probability of obtaining a decisive result.

The parameters of the tagging software must be calibrated so as to ensure a tagging level which is sufficient to ensure rapid identification of the code, and said software may optionally adapt dynamically these parameters as a function of the result gradually obtained, as can be deduced easily by the person skilled in the art.

It has thus been shown that the described method and system achieve the intended aim and objects. In particular, it has been shown that the system thus conceived allows to overcome the quality limitations of the background art.

In particular, it has been found that since no extraneous sound is inserted in the audio, the tagging system described here ensures substantial inaudibility even if, due to the characteristics of the audio playback system that is used and/or of the listening environment, the masking frequencies are attenuated or the masked frequencies are boosted to the point that the theoretically inaudible code becomes instead audible for the human ear.

Moreover, the described invention keeps unchanged the sound matching system, thus allowing to provide listening data which are reliable also for the radio and television stations which, for various reasons, decide not to tag their own audio, by using a single acquisition device, integrating the functions of audio tagging comparison and received audio comparison.

Clearly, numerous modifications are evident and can be performed promptly by the person skilled in the art without abandoning the scope of the protection of the present invention. For example, it is obvious for the person skilled in the art to vary the sampling parameters or the comparison times between two sample sequences.

Likewise, it is within the common knowledge of any information-technology specialist to implement programmatically the described tagging and comparison methods by using optimization techniques which do not alter the inventive concept on which the invention is based.

Therefore, the scope of the protection of the claims must not be limited by the illustrations or by the preferred embodiments given in the description by way of example, but rather the claims must comprise all the characteristics of patentable novelty that reside within the present invention, including all the characteristics that would be treated as equivalent by the person skilled in the art.

The disclosures in Italian Patent Application No. MI2005A002196 from which this application claims priority are incorporated herein by reference.

What is claimed is:

1. A tagging method adapted to insert, in audio generated by an audio source and represented in the frequency domain, an identification code which comprises a predefined number of bits, which comprises the steps of:
a) associating with each bit of said code a corresponding frequency interval;
b) applying a bandpass filter centered on each of said frequency intervals associated with said bits of said code, such that:
if the bit has the value 1, the value of the corresponding frequency interval is amplified;
if the bit has the value 0, the value of the corresponding frequency interval is attenuated.

2. The method according to claim 1, wherein said identification code comprises 10 to 20 bits, preferably 15.

3. The method according to claim 1, wherein said bandpass filter reaches frequency intervals which are adjacent to the frequency interval on which it is centered, amplifying or attenuating said adjacent intervals to a lesser extent with respect to the interval on which the bandpass filter is centered.

4. The method according to claim 3, wherein said bandpass filter reaches the directly preceding frequency interval and the directly following frequency interval with respect to the frequency interval on which it is centered.

5. The method according to claim 1, wherein a distance between two frequency intervals used to represent a respective bit of said code is such that a same frequency is subjected at the most to one amplification or attenuation.

6. The method according to claim 1, wherein said code is inserted in both channels of a stereophonic audio source.

7. An audio tagging device, adapted to insert in audio generated by an audio source and represented in the frequency domain, an identification code which comprises a predefined quantity Q of bits, comprising:
a) means for associating with each bit of said code a corresponding frequency interval;
b) means for applying a bandpass filter centered on each of said frequency intervals associated with said bits of said code, such that:
if the bit has the value 1, the value of the corresponding frequency interval is amplified;
if the bit has the value 0, the value of the corresponding frequency interval is attenuated.

8. The audio tagging device according to claim 7, wherein said identification code comprises 10 to 20 bits, preferably 15.

9. The audio tagging device according to claim 7, wherein said bandpass filter reaches frequency intervals which are adjacent to the frequency interval on which it is centered, amplifying or attenuating said adjacent intervals to a lesser extent than the interval on which the bandpass filter is centered.

10. The audio tagging device according to claim 9, wherein said bandpass filter reaches a directly preceding frequency interval and a directly following frequency interval with respect to the frequency interval on which it is centered.

11. The audio tagging device according to claim 10, wherein a distance between two frequency intervals used to represent a respective bit of said code is such that a same frequency is subjected at most to one amplification or attenuation.

12. A device for recognizing audio tagging performed by a tagging device according to claim 7.
